(19) United States
(12) Patent Application Publication
(10) Pub. No.: US 2025/0130271 A1
(43) Pub. Date: Apr. 24, 2025

(54) METHOD FOR INSPECTING LIGHT EMITTING DIODE PACKAGE

(71) Applicant: Taiwan-Asia Semiconductor Corporation, Hsinchu City (TW)

(72) Inventors: Chih-Hung CHEN, Hsinchu City (TW); Hui-Chen KUO, Hsinchu City (TW)

(21) Appl. No.: 18/800,355

(22) Filed: Aug. 12, 2024

(30) Foreign Application Priority Data
Oct. 20, 2023 (TW) 112140309

(51) Int. Cl. G01R 31/26

(52) U.S. Cl. CPC G01R 31/2635; G01R 31/2644

(57) ABSTRACT

A method for inspecting a light-emitting diode package is provided. The inspecting method comprises the following steps. First, provide a light-emitting diode package, wherein the light-emitting diode package includes a light-emitting diode chip, a lead frame and an encapsulation body. The light-emitting diode chip is disposed on the lead frame and the height of the lead frame is higher than that of the light-emitting diode chip. The encapsulation body covers the light-emitting diode chip and a portion of the lead frame. Next, remove a portion of the encapsulation body to expose the upper surface of the light-emitting diode chip.

### CROSS-REFERENCES TO RELATED APPLICATIONS

This application claims the benefit of priority to Taiwanese Patent Application No. 112140309 filed on Oct. 20, 2023, which is hereby incorporated by reference in its entirety.

### BACKGROUND OF THE INVENTION

### Field of the Invention

The present invention relates to a method for inspecting a light-emitting diode package, and in particular, to an inspection method that provides a cross-section of a light-emitting diode package.

### Descriptions of the Related Art

Light-emitting diodes are widely used in lighting, display and other fields due to their small size, long life, energy saving and high efficiency. Light-emitting diodes have a variety of package structures. The common plug-in light-emitting diodes (Lamp LED) are available in various types such as 3 mm, 5 mm, round, concave, oval, square, or the like, and can be widely used in consumer products, home appliances, traffic signals, outdoor displays and industrial equipment and other applications.

Please refer to FIG. 1, which shows a common plug-in light-emitting diode package. The basic components of this type of plug-in light-emitting diode package 1 include a light-emitting diode chip 10, a lead frame 20 and an encapsulation body 30. The light-emitting diode chip 10 is fixed on the lead frame 20. The lead frame 20 has two independent electrode terminals that are electrically connected to the anode and cathode of the light-emitting diode chip 10 respectively. The encapsulation body 30 covers the light-emitting diode chip 10 and a portion of the lead frame 20.

In order to effectively control the production quality of the above-mentioned light-emitting diode package, it is necessary to perform failure analysis on the package. One of the common analysis methods is to use grinding and ion-beam cutting to profile the light-emitting diode package and to contact with the light-emitting diode to form the cross-sections between each component in the light-emitting diode package. Through cross-section analysis, the defects and their possible causes between each component in the above-mentioned package will be probably found out and their improvement plans will be proposed accordingly.

However, after grinding and cutting the light-emitting diode package, the components in the package often become separated from each other. As shown in FIG. 2, it is clearly shown that there are cracks between the encapsulation body 30 and the lead frame 20, between the silver glue 40 and the lead frame 20, and between the silver glue 40 and the light-emitting diode chip 10. However, these cracks may be caused by abnormal manufacturing processes of light-emitting diode package, or by the inspection processes of the grinding, cutting or profiling as mentioned above. Current inspection methods cannot clarify the cause of cracks, which will affect subsequent judgments of quality defects.

To address the issues mentioned above, the industry urgently requires an innovative inspection method that can mitigate unexpected cracks in package devices resulting from improper grinding and cutting. This method aims to accurately identify the causes of abnormalities in the package production process and minimize the impact of cracks caused by improper grinding and cutting during the inspection process on abnormal judgments.

### SUMMARY OF THE INVENTION

One main objective of this invention is to offer an innovative method for inspecting light-emitting diode packages, aimed at reducing unexpected cracks in the package devices resulting from improper grinding and cutting. Additionally, the method seeks to minimize the abnormal impact of such cracks occurring during the inspection process due to improper grinding and cutting. Ultimately, the goal is to accurately determine the true cause of abnormalities in the package production process.

To achieve the above objective, the present invention discloses a method for inspecting a light-emitting diode package. The inspecting method comprises the following steps. First, provide a light-emitting diode package, wherein the light-emitting diode package includes a light-emitting diode chip, a lead frame and an encapsulation body. The light-emitting diode chip is disposed on the lead frame and the height of the lead frame is higher than that of the light-emitting diode chip. The encapsulation body covers the light-emitting diode chip and a portion of the lead frame. Next, remove a portion of the encapsulation body to expose the upper surface of the light-emitting diode chip.

In one embodiment of the present invention, the method for inspecting a light-emitting diode package further comprises the step of removing a portion of the encapsulation body on one side of the light-emitting diode chip.

. In one embodiment of the present invention, the method for inspecting a light-emitting diode package further comprises the step of polishing the light-emitting diode chip with ion beams to form a cross-section of the light-emitting diode package.

In one embodiment of the method for inspecting a light-emitting diode package of the present invention, the step of removing a portion of the encapsulation body to expose the upper surface of the light-emitting diode chip is to use a grinding wheel to grind the portion of the encapsulation body above the upper surface of the light-emitting diode chip.

In one embodiment of the method for inspecting a light-emitting diode package of the present invention, the step of removing a portion of the encapsulation body on one side of the light-emitting diode chip is to use a grinding wheel to grind the portion of the encapsulation body on the side of the light-emitting diode chip.

In one embodiment of the method for inspecting a light-emitting diode package of the present invention, the light-emitting diode package further comprises a conductive glue for fixing the light-emitting diode chip on the lead frame.

In one embodiment of the method for inspecting a light-emitting diode package of the present invention, the light-emitting diode chip is one of a horizontal light-emitting diode chip or a vertical light-emitting diode chip.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 shows a schematic diagram of a conventional plug-in light-emitting diode package structure.

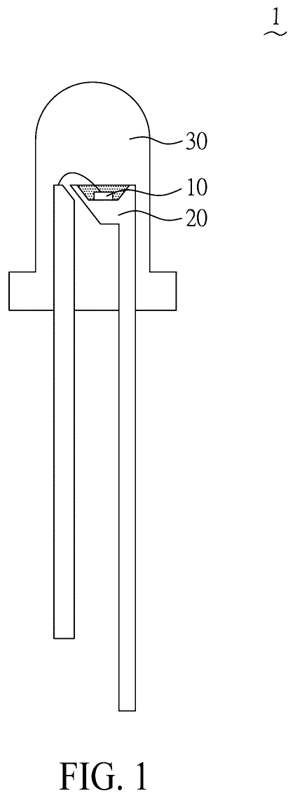

FIG. 2 shows an actual cross-sectional SEM photograph of a conventional plug-in light-emitting diode package after grinding and cutting.

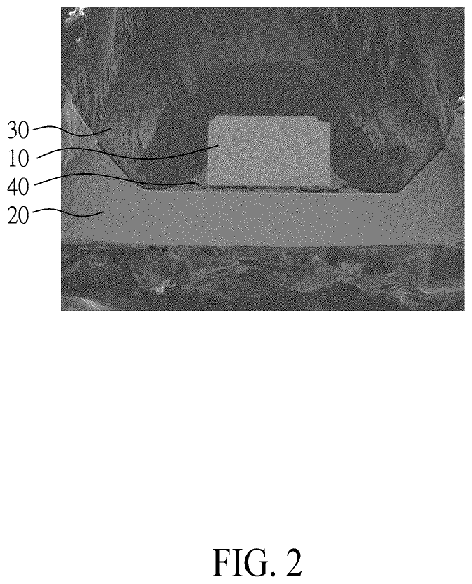

FIG. 3 shows a schematic diagram of a part of the structure of a plug-in light-emitting diode package to be tested in an embodiment of the inspection method according to the present invention.

FIG. 4 shows a partial perspective view of a plug-in light-emitting diode package being tested in an embodiment of the inspection method according to the present invention.

FIG. 5 shows an actual cross-sectional SEM photograph of the package component after cutting in an embodiment of the inspection method according to the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

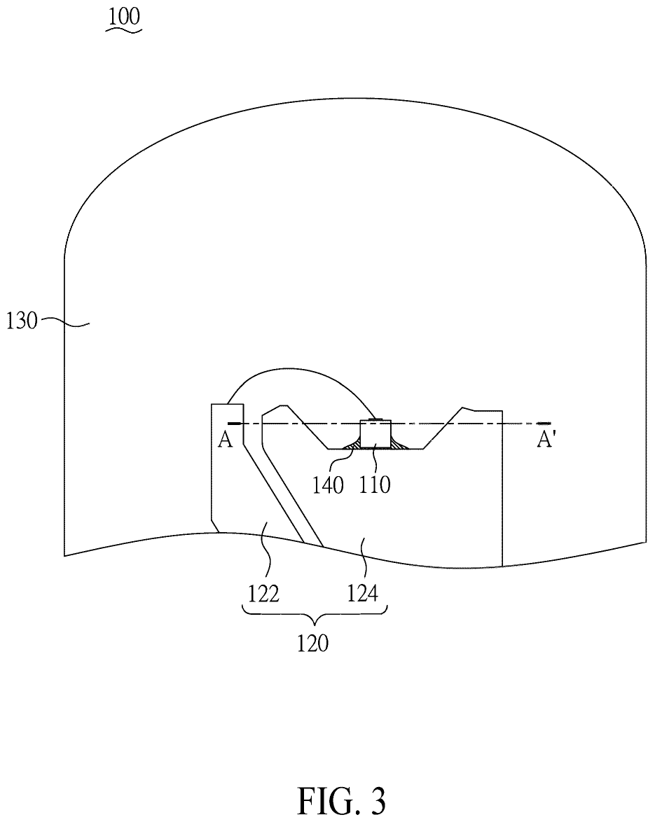

Please refer to FIG. 3, which illustrates a partial structural diagram of a plug-in light-emitting diode package to be inspected in an exemplary embodiment of the present invention's inspection method. The plug-in light-emitting diode package 100 shown in the figures share the same basic composition as commonly conventional light-emitting diode package structures, comprising a light-emitting diode chip 110, a lead frame 120, an encapsulation body 130, and a conductive glue 140. The light-emitting diode chip 110 can be either a common horizontal or vertical type. In the embodiment shown in the present invention, the light-emitting diode chip 110 adopts a vertical structure. Additionally, the lead frame 120 has two independent electrode terminals, namely, the anode terminal 122 and the cathode terminal 124. The upper half of the cathode terminal 124 features a concave cup structure with a wider upper part and a narrower lower part. Both the height of the anode terminal 122 and the cathode terminal 124 of the lead frame 120 are higher than that of the light-emitting diode chip 110 so the concave cup structure is able to accommodate the light-emitting diode chip. The light-emitting diode chip 110 is bonded to one end of the cathode terminal 124 using conductive glue 140, such as silver glue, and electrically connected to it. Specifically, the anode terminal 122 of the lead frame 120 is electrically connected to the upper electrode of the light-emitting diode chip 110, and the cathode terminal 124 of the lead frame 120 is electrically connected to the lower electrode at the back of the light-emitting diode chip 110. The encapsulation body 130 covers the entire light-emitting diode chip 110, conductive glue 140, and a portion of the lead frame 120, and can be made of epoxy resin.

The present invention utilizes finite element analysis to explore the stress distribution among the components of a conventional light-emitting diode package structure, including a light-emitting diode chip, a conductive glue, a lead frame, and an encapsulation body. It is found that the bottom of the light-emitting diode chip bears the highest stress. If the conventional inspection method directly uses a cross-section polisher for grinding and cutting, improper stress transmission to the encapsulation structure will cause expansion of the encapsulation body, squeezing of the light-emitting diode chip, and lifting it upwards. This, in turn, leads to unexpected separation between the encapsulation body and the lead frame, between the conductive glue and the lead frame, and between the conductive glue and the chip. Therefore, the present invention proposes an innovative inspection method to reduce unexpected cracks caused by improper stress transmission during grinding and cutting.

Please continue to refer to FIG. 3. In order to reduce the improper transmission of stress to the interior of the encapsulation structure during grinding and cutting, the inspection method of the present invention conducts grinding and cutting in a segmented manner. Specifically, firstly, a portion of the encapsulation body 130 of the light-emitting diode package 100 is removed from the top using a grinding wheel, for example, removing a portion of the encapsulation body 130 from the upper surface of the light-emitting diode chip 110, until the upper surface of the light-emitting diode chip 110 is exposed. As shown in FIG. 3, the top grinding cutoff line for the first stage of grinding is set along the section line A-A′, ensuring that no encapsulation body remains on the upper surface of the light-emitting diode chip 110. In a preferred embodiment, this first stage of grinding and cutting can be further divided into two stages. Firstly, coarse grinding wheel is used to remove a portion of the encapsulation body 130 from the top of the light-emitting diode package 100 to the portion outside of the lead frame 120. Then, a fine grinding wheel is used to remove a remaining portion of the encapsulation body 130 from the lead frame 120 to the light-emitting diode chip 110, until the upper surface of the light-emitting diode chip 110 is exposed.

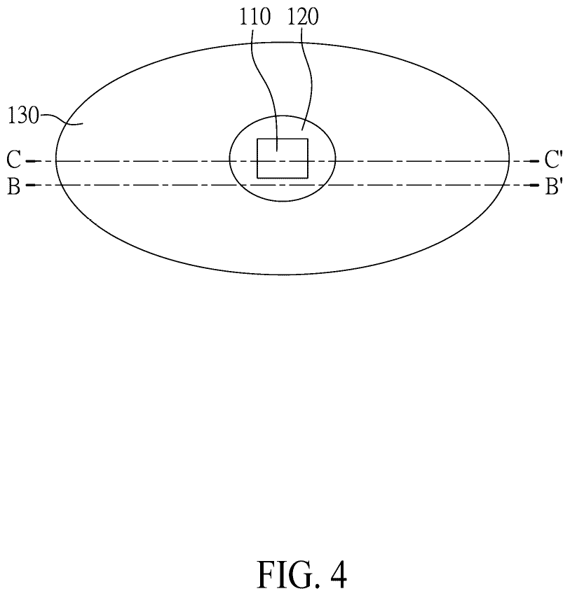

Next, please also refer to FIG. 4, which shows a partial perspective view of the light-emitting diode chip 110, the lead frame 120, and the encapsulation body 130 within the light-emitting diode package 100. It should be noted that the contours and dimensions of the components shown in FIG. 4 are for illustrative purposes only and do not represent the actual contours or dimensions of the package. In a preferred embodiment, after removing a portion of the encapsulation body 130 from the top of the light-emitting diode package 100, the grinding process continues by using a grinding wheel to grind the side of the light-emitting diode package 100 for removing a portion of the encapsulation body 130 from one side of the light-emitting diode chip 110. As shown in FIG. 4, the section line B-B′ is used as the cutoff line for the side grinding of the second stage of grinding. It should be noted that this grinding stage only needs to grind up to the side of the light-emitting diode chip 110, and it is not necessary to expose the side of the light-emitting diode chip 110.

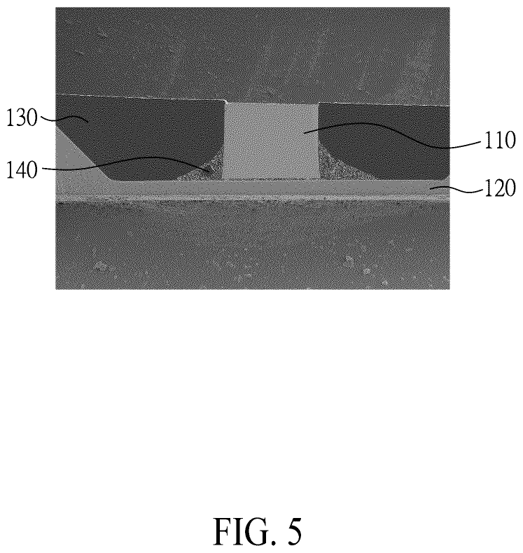

Then, proceed to the third stage of grinding and cutting. In this stage, an ion beam is used to continue grinding and cutting the light-emitting diode package 100 using a cross-section polisher, as shown in FIG. 4. Starting from the section line B-B′, the ion beam is continuously applied to polish the package 100 until the cross-section line C-C′ is reached and the cross-section of the light-emitting diode package is formed. Please refer to FIG. 5, which shows an actual cross-sectional SEM (Scanning Electron Microscope) photograph of a light-emitting diode package after using the method for inspecting a light-emitting diode package of the present invention.

As shown in FIG. 5, because the entire process of cross-section grinding has been divided into several different grinding and cutting stages, the stress generated during the grinding and cutting process can be effectively released in stages without being transmitted to the components within the package structure. This substantially reduces the impact on the light-emitting diode chip and other components. Especially in the first stage, where most of the encapsulation body between the top of the package and the surface of the chip has been removed, the stress from subsequent grinding and cutting no longer significantly affects the rigid strength of the components within the package at this stage. Therefore, the integrity of the original structure of the light-emitting diode chip 110, lead frame 120, encapsulation body 130, and conductive glue 140 within the light-emitting diode package 100 can be maintained, without causing unexpected separation cracks between these components. This allows subsequent abnormal analysis and judgment of the product able to identify the correct cause of process abnormalities so the inspection method will become more accurate.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A method for inspecting a light-emitting diode package, comprising:
providing a light-emitting diode package, wherein the light-emitting diode package includes a light-emitting diode chip, a lead frame and an encapsulation body, the light-emitting diode chip is disposed on the lead frame and the height of the lead frame is higher than that of the light-emitting diode chip, and the encapsulation body covers the light-emitting diode chip and a portion of the lead frame; and
removing a portion of the encapsulation body to expose the upper surface of the light-emitting diode chip.

2. The method for inspecting a light-emitting diode package of claim 1, further comprising a step of removing a portion of the encapsulation body on one side of the light-emitting diode chip.

3. The method for inspecting a light-emitting diode package of claim 2, further comprising a step of polishing the light-emitting diode chip with ion beams to form a cross-section of the light-emitting diode package.

4. The method for inspecting a light-emitting diode package of claim 1, wherein the step of removing a portion of the encapsulation body to expose the upper surface of the light-emitting diode chip is to use a grinding wheel to grind the portion of the encapsulation body above the upper surface of the light-emitting diode chip.

5. The method for inspecting a light-emitting diode package of claim 2, wherein the step of removing a portion of the encapsulation body on one side of the light-emitting diode chip is to use a grinding wheel to grind the portion of the encapsulation body on the side of the light-emitting diode chip.

6. The method for inspecting a light-emitting diode package of claim 1, wherein of the light-emitting diode package further comprises a conductive glue for fixing the light-emitting diode chip on the lead frame.

7. The method for inspecting a light-emitting diode package of claim 1, wherein the light-emitting diode chip is one of a horizontal light-emitting diode chip or a vertical light-emitting diode chip.
